(19) United States
(12) Patent Application Publication
(10) Pub. No.: US 2004/0019735 A1
(43) Pub. Date: Jan. 29, 2004

(54) Method for capturing characters of a file without need to recognize the file format

(76) Inventors: Peng-Cheng Huang, Panchiao City (TW); Meng-Hsiang Lin, Panchiao City (TW)

Correspondence Address: DELLETT AND WALTERS, 310 S.W. FOURTH AVENUE, SUITE 1101, PORTLAND, OR, 97204, US

(21) Appl. No.: 10/208,452

(22) Filed: Jul. 29, 2002

(51) Int. Cl. G11C 5/00

(52) U.S. Cl. 711/1

(57) ABSTRACT

A method for capturing characters of a file utilizes a printer driver program to capture the characters. Since a file is intended to be printed, the characters is distinguished from image codes of the file by the printer driver program, the characters thus is able to be intercepted and captured during the file printing process. The captured characters that represent text contents of the file are further provided to created and expand a database. Therefore, the database has the searchable text contents, i.e. the captured characters, without any need of a file format recognizing process.

### BACKGROUND OF THE INVENTION

1. Field of the Invention

The present invention relates to a method for capturing characters of a file, and more particularly to a method that utilizes a printer driver program to capture the characters of a file without needing to recognize the file format.

2. Description of Related Art

One important factor to cause the Internet to become so popular is that the Internet acts as a continuously growing and largest databank in the world. Actually, to create a complete database must undergo many particular processing and management procedures. Usually, if the shared/public information is intended to be uploaded to a database, an application program that can recognize varied formats of those transmitted information is developed to capture the text content contained in that information. Thereby the captured text content can be further employed as the searchable strings or objects for the database.

Generally, the database requires different application programs as the accessing interfaces between the database and a client user. When the client user transmits different files with different formats into the database, the corresponding application program must have the ability to analyze the file format. Otherwise, the text content of the file can not be used as the searchable objects for the database, and thus the database expansion is limited.

Moreover, the file format recognition still has some problems that need to be overcome. Firstly, the program designers must be familiar with all kinds of file formats so that they can analyze different files. At present, there is no general way that can transmit shared data into a database and further make that data become the searchable items for the database. Actually, although the already used file formats are more than thousands, it is impossible to recognize all kinds of file formats.

Secondly, if the file format is developed specially for a company, such as accounting reports of the company, the unique and specific file may be able to be printed out via its particular application program, but still can not be analyzed by an ordinary application program. Thus the text content of this file can not be employed as the searchable items for the database.

To overcome the shortcomings, a method for capturing characters of a file without needing to recognize the file format in accordance with the present invention obviates or mitigates the aforementioned drawbacks.

### SUMMARY OF THE INVENTION

The main objective of the present invention is to provide a method for capturing characters that represent the text content of a file, without any file recognizing process.

To achieve the objective, the capturing method comprises the steps of:

executing a characters capturing means to obtain the characters of a file, wherein the characters represent the text content of the file;

storing the captured characters; and

creating and storing indexes related to the captured characters;

wherein since the characters of the file are directly captured without any file format recognizing process via a printer driver program in accordance with the present invention, there is no need to develop different application programs to correspond to particular file formats, and the captured characters that represent the text content of the file are able to be further applied and employed;

Other objectives, advantages and novel features of the invention will become more apparent from the following detailed description when taken in conjunction with the accompanying drawings.

### BRIEF DESCRIPTION OF THE DRAWINGS

FIG. 1 is a flow chart of a method for capturing character information in accordance with the present invention;

FIG. 2 is a flow chart of another embodiment of the method for capturing character information in accordance with the present invention;

FIG. 3 is a flow chart showing an encoding and transmitting process in accordance with the present invention; and

FIG. 4 is a flow chart showing a decoding and receiving process in accordance with the present invention.

### DETAILED DESCRIPTION OF THE PREFERRED EMBODIMENT

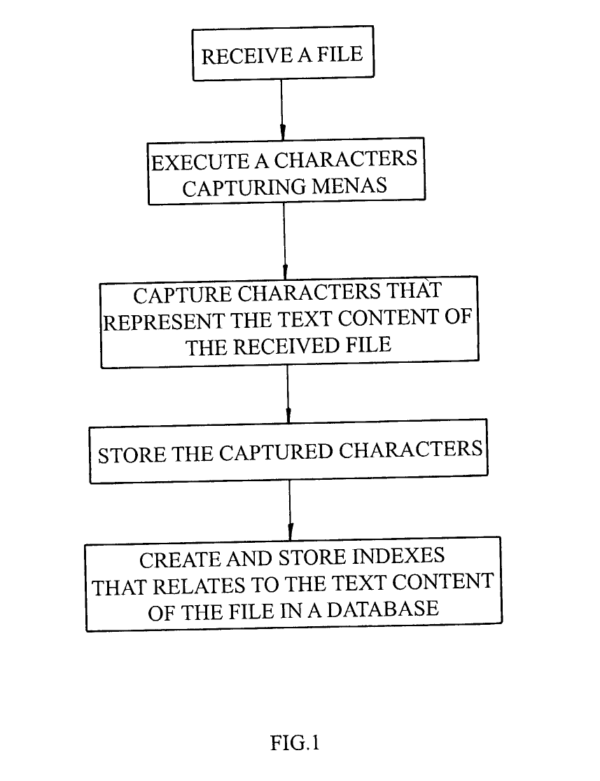

With reference to FIG. 1, the method for capturing characters of a file without needing to recognize the file format of the present invention comprises the steps of:

receiving a file;

executing a characters capturing means to capture characters of the received file, wherein the captured characters represent the text content of the file;

storing the captured characters; and

creating and storing indexes related to the text content.

The advantage of the method is that the characters of the file are directly captured without need for a particular application program that recognizes the file format. Therefore, despite the file formats and any images contained in the file, the text content of the file can be obtained and further employed as the searchable objects for a database.

The characters capturing means is performed by a printer driver program in accordance with the present invention. When a file is transmitted to a printer to be printed out via an application program, the text content and any pictures contained in the file would be respectively converted into binary forms, i.e. the characters and image codes.

Since characters and image codes contained in a file to be printed both are transmitted to the printer driver program, the characters that represent the text content of the file are captured via the printer driver program. Thereafter the captured characters will further be applied to a database for the use of searchable objects for the database.

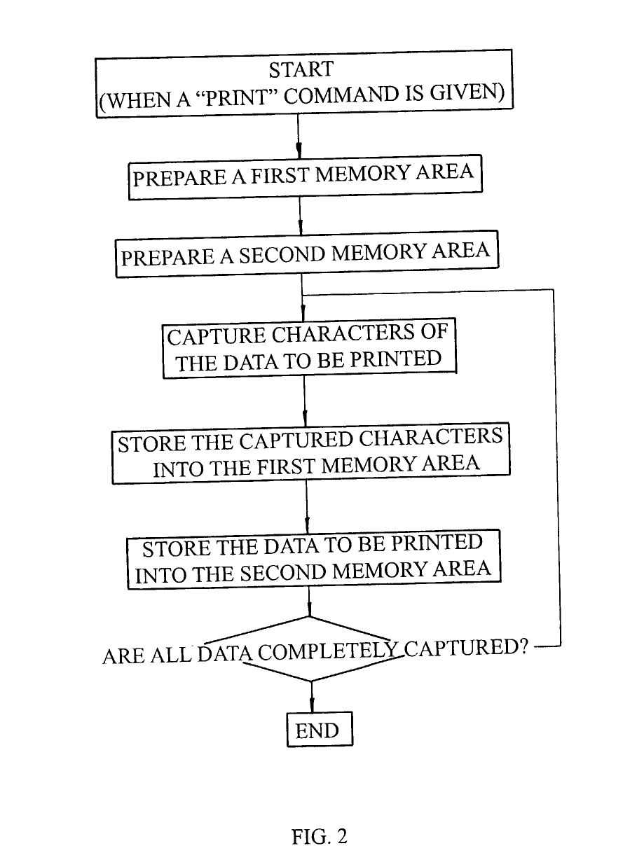

With reference to FIG. 2, when the characters capturing means is preferably performed by the printer driver program, the present invention is shown in more detail in FIG. 2, and the detailed steps are:

(a) Prepare a first memory area, a second memory area and a printer driver program that is able to capture characters of a file, wherein the first memory area is to store the captured characters, and the second memory is provided to store the data to be printed.

(b) Install the printer driver program. More particularly, the printer driver program supports all kinds of application programs. As discussed foregoing, when a file is intended to be printed, the characters and the image codes of the data to be printed are both transmitted to the printer driver program. The printer driver program is applied to intercept and capture the characters.

(c) Capture characters of the file. The captured characters are further stored in the first memory area, wherein the data intended to be printed is stored in the second memory area.

(d) Repeat step (c) until all data intended to be printed being completely captured.

(e) Store all the captured characters and all data to be printed into a database, whereby a user is able to search the data in the database.

Moreover, the character capturing method of the present invention can be further combined with a second system and a third system to construct a complete database application system. The printer driver program for capturing characters mentioned foregoing is deemed as a first system. An encoding process to the captured characters is performed by the second system, and the decoding processes are achieved by the third system. The encoding and decoding steps are described hereinafter.

(a) Encode the captured characters stored in the first memory area and the captured data stored in the second memory area. Here, the purpose of the encoding process is to compress the size of the data. Therefore, the transmission time can be reduced when those encoded characters and data are transmitted to the third system.

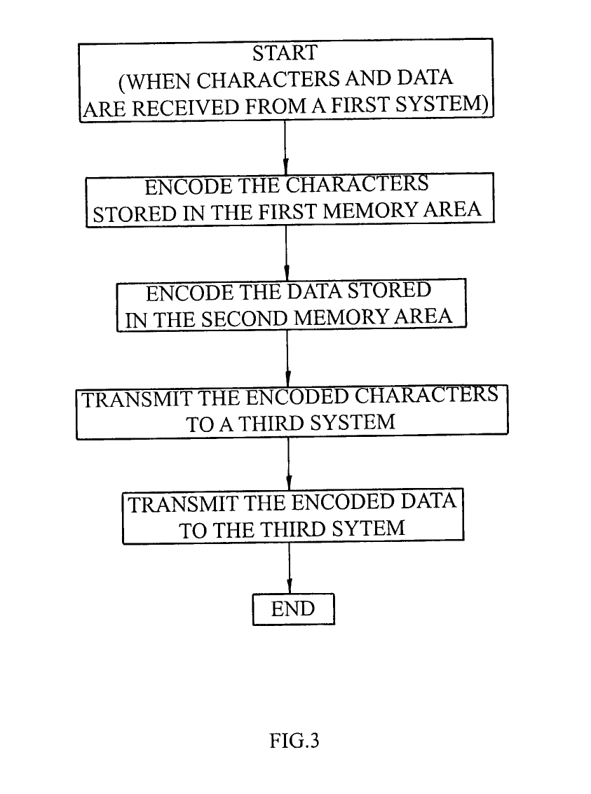

After encoding the characters and data, both are transmitted to the third system that has ability to decode those encoded information (as shown in FIG. 3).

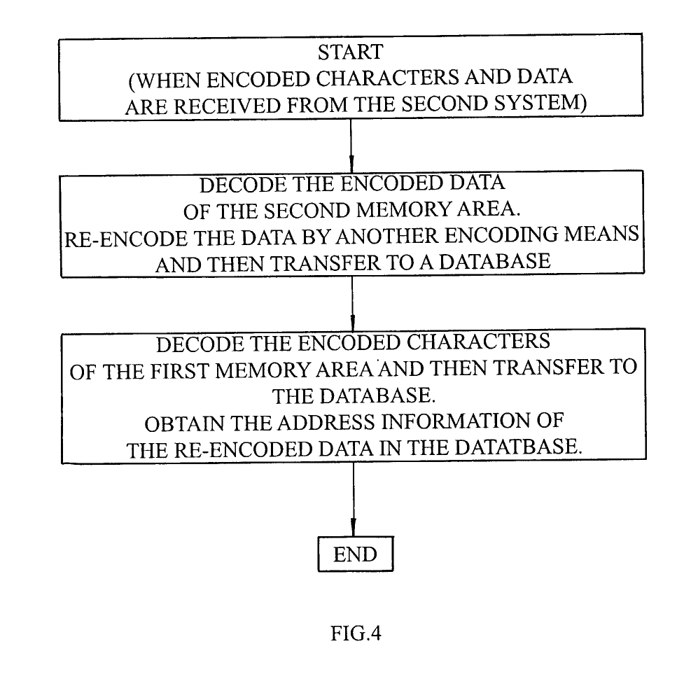

(b) When the third system receives the encoded characters and the encoded data, the third system starts to decode those encoded characters and data. The decoded characters are directly transferred to and stored in a database. The decoded data, which is originally stored in the second memory area, is re-encoded by another type of encoding means again and then transfer to a database (as shown in FIG. 4). For example, the re-encoding process is a file format encoding process that converts the data into a particular file format, such as a PDF, TIFF, or WMF file format. Therefore, the data with PDF, TIFF, or WMF format are stored in the database and acted as the searchable objects.

(c) Since the decoded characters and the re-encoded data are both stored in the third system, the third system further creates the indexes that represent the relation ship between the characters and the re-encoded data. For example, the indexes are path information of the re-encoded data in the database. Thus, when a user searches out a file in the data base by the characters, the path information will direct to a particular address in the database to correspond to the file, i.e. the re-encoded data.

The foregoing illustration of the preferred embodiments in the present invention is intended to be illustrative only, under no circumstances should the scope of the present invention be so restricted.

What is claimed is:

1. A method for capturing characters of a file, wherein the data of the file at least include characters that represent text content of the file, the method comprising the steps of:
capturing characters of a file, wherein the characters represent text content of the file;
storing the captured characters in a database; and
creating indexes related to the text content of the file, whereby the captured characters are able to used as searchable objects for the database.

2. The method as claimed in claim 1, wherein the characters capturing is performed by a printer driver program.

3. The method as claimed in claim 2, wherein before the character capture step, the method further comprising the steps of:
preparing a first memory area, a second memory area and the printer driver program that is able to capture characters;
installing the printer driver program, wherein the characters and image codes of the file are transferred to the printer driver program;
wherein the characters capturing step further comprises the steps of:
capturing the characters of the file when the characters and the image codes of the file are transferred to the printer driver program, wherein the captured characters are stored in the first memory area, and the data to be printed are stored in the second area;
repeating the characters capturing step to all completely captured characters of the file;
transferring the captured characters in the first memory area and the data in the second memory area into the database so as to allow a user to search the database.

4. The method as claimed in claim 3, wherein the first memory area is for storage of the captured characters, and the second memory area is for storage of the data to be printed.
